(19) United States
(12) Patent Application Publication
(10) Pub. No.: US 2016/0029511 A1
(43) Pub. Date: Jan. 28, 2016

(54) ELECTRONIC DEVICE INCLUDING HEATING ELEMENT

(71) Applicants: Samsung Electronics Co., Ltd, Gyeonggi-do (KR); TTM Co., Ltd, Daejeon (KR)

(72) Inventors: Chung-Hyo Jung, Gyeonggi-do (KR); Eu-Gene Choi, Daejeon (KR); Bong-Jae Rhee, Gyeonggi-do (KR)

(21) Appl. No.: 14/809,094

(22) Filed: Jul. 24, 2015

(30) Foreign Application Priority Data
Jul. 25, 2014 (KR) 10-2014-0094685

(51) Int. Cl. H05K 7/20; F28F 23/00; F28F 21/00

(52) U.S. Cl. CPC H05K 7/2029; F28F 21/00; F28F 23/00

(57) ABSTRACT

A heat transfer apparatus is provided. The heat transfer apparatus includes a first thermal conductor. The heat transfer apparatus also includes a second thermal conductor. The heat transfer apparatus further includes an interface member configured to transfer heat between the first thermal conductor and the second thermal conductor. A portion of the interface member contains a thermoplastic material reacting via an application of the heat.

### CROSS-REFERENCE TO RELATED APPLICATION AND CLAIM OF PRIORITY

The present application is related to and claims benefit under 35 U.S.C. § 119(a) to Korean Application Ser. No. 10-2014-0094685, which was filed in the Korean Intellectual Property Office on Jul. 25, 2014, the entire content of which is hereby incorporated by reference.

### TECHNICAL FIELD

The present disclosure relate to an electronic device including a heating element.

### BACKGROUND

Recently, with the development of electronic communication industries, user devices (such as smart phones, tablet computers, or the like) have become necessities in modern society and important means for transferring fast-changing information. Such user devices have reached a stage of making users' operation convenient through a Graphical User Interface (GUI) environment using a touch screen and providing various multimedia based on a web environment.

In addition, the user devices have various electronic components mounted thereto in order to provide various functions. For example, the user devices have a stereo speaker module mounted thereto to provide a function of listening to music using stereo sound. Furthermore, the user devices have a camera module mounted thereto to provide a function of taking a photo. Moreover, the user devices have a communication module mounted thereto to provide a function of communicating with other electronic devices through a network. However, such electronic components may generate heat while operating, and the generated heat may cause damage to the electronic components or degradation in the performance thereof.

The above information is presented as background information only to assist with an understanding of the present disclosure. No determination has been made, and no assertion is made, as to whether any of the above might be applicable as prior art with regard to the present disclosure.

### SUMMARY

To address the above-discussed deficiencies, it is a primary object to provide at least the advantages described below. According, an aspect of the present disclosure may effectively transfer heat between thermal conductors.

Another aspect of the present disclosure improves contact with the thermal conductors.

In a first example, a heat transfer apparatus is provided. The heat transfer apparatus includes a first thermal conductor. The heat transfer apparatus also includes a second thermal conductor. The heat transfer apparatus further includes an interface member to transfer heat between the first and second thermal conductors. A portion of the interface member contains a thermoplastic material reacting with the heat.

A portion (such as a phase change material) of heat transfer materials (such as Thermal Interface Materials (TIMs)) is changed from the solid phase to the liquid phase by heat. The portion of the heat transfer materials is stably disposed between thermal conductors to improve contact with the thermal conductors and increase the amount of transferred heat.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example sheet according to this disclosure;

FIG. 2 illustrates an example procedure of manufacturing a sheet according to this disclosure;

FIGS. 3A, 3B, and 3C illustrate example processes for sheet mounting according to this disclosure;

FIGS. 4A, 4B, and 4C illustrate example processes for sheet mounting according to this disclosure;

FIG. 5 illustrates an example of using a sheet according to this disclosure;

FIG. 6 illustrates an example sheet according to this disclosure;

FIG. 7A illustrates an example electronic device according to this disclosure;

FIG. 7B is a sectional view of an example electronic device according to this disclosure;

FIG. 8 is an exploded perspective view of an example electronic device according to this disclosure;

FIG. 9 illustrates an example display set according to this disclosure;

FIG. 10 illustrates a combination between an example display set and an example Printed Board Assembly (PBA) according to this disclosure; and

FIG. 11 is a block diagram of an example electronic device according to this disclosure.

Throughout the drawings, it should be noted that like reference numbers are used to depict the same or similar elements, features, and structures.

### DETAILED DESCRIPTION

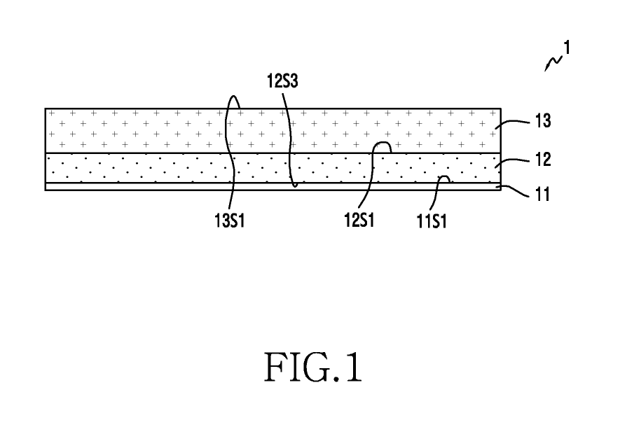

FIGS. 1 through 11, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged electronic device. The following description with reference to the accompanying drawings is provided to assist in a comprehensive understanding of various embodiments of the present disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the present disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the present disclosure. Accordingly, it should be apparent to those skilled in the art that the following description of various embodiments of the present disclosure is provided for illustration purpose only and not for the purpose of limiting the present disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

The expressions “include”, “may include”, etc. as used in the present disclosure refers to the existence of a corresponding disclosed function, operation or component which may be used in various embodiments of the present disclosure and does not limit one or more additional functions, operations, or components. In the present disclosure, the expressions such as “include”, “have”, etc. as used in the present disclosure may be construed to denote a certain characteristic, number, step, operation, constituent element, component or a combination thereof but may not be construed to exclude the existence of or a possibility of addition of one or more other characteristics, numbers, steps, operations, constituent elements, components or combinations thereof. The expression “or”, etc. as used in various embodiments of the present disclosure includes any or all of combinations of listed words, For example, the expression “A or B” may include A, may include B, or may include both A and B.

The expression “1”, “2”, “first”, or “second” used in various embodiments of the present disclosure may modify various components of various embodiments but does not limit the corresponding components. For example, the above expressions do not limit the sequence and/or importance of the elements. The above expressions are used merely for the purpose of distinguishing an element from the other elements. For example, a first user device and a second user device indicate different user devices although both of them are user devices. For example, without departing from the scope of the present disclosure, a first component element may be named a second component element. Similarly, the second component element also may be named the first component element.

It should be noted that if it is described that one component element is “coupled” or “connected” to another component element, the first component element may be directly coupled or connected to the second component, and a third component element may be “coupled” or “connected” between the first and second component elements. Conversely, when one component element is “directly coupled” or “directly connected” to another component element, it may be construed that a third component element does not exist between the first component element and the second component element.

The terms in various embodiments of the present disclosure are used to describe various embodiment, and are not intended to limit the present disclosure. As used herein, the singular forms are intended to include the plural forms as well, unless the context clearly indicates otherwise.

Unless defined differently, all terms used herein, which include technical terminologies or scientific terminologies, have the same meaning as a person skilled in the art to which the present disclosure belongs. Such terms as those defined in a generally used dictionary are to be interpreted to have the meanings equal to the contextual meanings in the relevant field of art, and are not to be interpreted to have ideal or excessively formal meanings unless clearly defined in the present disclosure.

An electronic device according to various embodiments of the present disclosure may be a device with a communication function. For example, the electronic device may include at least one of a smart phone, a tablet personal computer (PC), a mobile phone, a video phone, an e-book reader, a desktop PC, a laptop PC, a netbook computer, a personal digital assistant (PDA), a portable multimedia player (PMP), an MP3 player, a mobile medical device, a camera, a wearable device (such as a head-mounted-device (HMD) such as electronic glasses, electronic clothes, an electronic bracelet, an electronic necklace, an electronic appcessory, an electronic tattoo, a smart watch, or the like).

According to various embodiments, the electronic device can be a smart home appliance with a communication function. The smart home appliance as an example of the electronic device may include at least one of, for example, a television, a Digital Video Disk (DVD) player, an audio, a refrigerator, an air conditioner, a vacuum cleaner, an oven, a microwave oven, a washing machine, an air cleaner, a set-top box, a TV box (such as SAMSUNG HOMESYNC™, APPLE TV™, or GOOGLETV™), a game console, an electronic dictionary, an electronic key, a camcorder, and an electronic picture frame.

According to various embodiments, the electronic device includes at least one of various medical appliances (such as Magnetic Resonance Angiography (MRA), Magnetic Resonance Imaging (MRI), Computed Tomography (CT) machine, and an ultrasonic machine), navigation devices, Global Positioning System (GPS) receivers, Event Data Recorders (EDRs), Flight Data Recorders (FDRs), automotive infortainment devices, electronic equipments for ships (such as navigation equipments for ships, gyrocompasses, or the like), avionics, security devices, head units for vehicles, industrial or home robots, Automatic Teller Machines (ATM) of banking facilities, and Point Of Sales (POSs) of shops.

According to various embodiments, the electronic device includes at least one of furniture or a part of a building/structure, an electronic board, an electronic signature receiving device, a projector, and various types of measuring devices (for example, a water meter, an electric meter, a gas meter, a radio wave meter and the like) including a camera function. An electronic device according to various embodiments of the present disclosure is a combination of one or more of above described various devices. Also, an electronic device according to various embodiments of the present disclosure is a flexible device. Also, an electronic device according to various embodiments of the present disclosure is not limited to the above described devices. Hereinafter, an electronic device according to various embodiments will be described with reference to the accompanying drawings. The term “user” used in various embodiments refers to a person who uses an electronic device or a device (for example, an artificial intelligence electronic device) that uses an electronic device.

FIG. 1 illustrates an example sheet according to this disclosure. Referring to FIG. 1, a thermal diffusion sheet, or simply a sheet 1, includes multiple layers. For example, the sheet 1 includes a first layer 11, a second layer 12, and a third layer 13. The first layer 11 is disposed below the second layer 12. The first layer 11 covers the lower surface 12S3 of the second layer 12 to protect the same. Here, the first layer 11 has a predetermined thickness. The first layer 11 is transparent. According to an embodiment, the first layer 11 includes a plastic film (such as a synthetic resin film, a vinyl film, a vinylidene film, a polyethylene film, a polypropylene film, or the like).

The second layer 12 is disposed above the first layer 12. The second layer 12 covers at least a portion of the upper surface 11S1 of the first layer 11. The second layer 12 has a thermal conductivity. For example, the second layer 12 has a thermal conductivity of 1 W/mk or more (such as 4 W/mk). Here, the second layer 12 has a thickness of 0.1 mm or more (such as 0.15 mm or 0.25 mm). Alternatively, the second layer 12 may or may not have an electrical conductivity. For example, in cases where the second layer 12 has an electrical conductivity, the second layer 12 shields electrical noise or Electro Magnetic Interference (EMI). In addition, the second layer 12 also has an excellent wear resistance or heat resistance.

The second layer 12 contains a thermoplastic material. According to an embodiment, the second layer 12 contains a Phase Change Material (PCM). The phase change material is changed from the solid phase into the liquid phase by heat. Here, a liquid phase change material has a viscosity. The liquid phase change material is compressible or incompressible. Alternatively, the second layer 12 contains a material of which at least one physical property is changed by heat. For example, the material of the second layer 12 has a high viscosity caused by heat.

The third layer 13 is disposed on the second layer 12. The third layer 13 covers at least a portion (such as the entirety of) of the upper surface 12S1 of the second layer 12. The third layer 13 has a thermal conductivity. For example, the third layer 13 has a thermal conductivity of 0.1 W/mk or more (such as 0.5 W/mk to 3 W/mk). Here, the third layer 13 has a thickness of 0.1 mm or more (such as 0.1 mm or 0.15 mm). The sum of the thicknesses of the second and third layers 12 and 13 is 0.2 mm or more (such as 0.25 mm or 0.4 mm).

Alternatively, the third layer 13 may or may not have an electrical conductivity. For example, the second layer 12 has an electrical conductivity, but the third layer 13 may not have an electrical conductivity. Alternatively, the second layer 12 may not have an electrical conductivity, but the third layer 13 has an electrical conductivity. The second layer 13 also has a wear resistance or heat resistance. The third layer 13 has an excellent mechanical property (such as a tensile strength or resilience) and resists tearing. The third layer 113 is cured when being heated.

According to an embodiment, the third layer 13 is formed in such a manner that the upper surface 12S1 of the second layer 12 is subjected to surface treatment using a thermal conductive material (such as silicon, silicone polymer, graphite, acrylic, or the like). The surface treatment increases a bonding force between the upper surface 12S1 of the second layer 12 and the thermal conductive material. Here, the third layer 13 contains at least one same material (such as silicone polymer) as the second layer 12. For example, the second layer 12 contains a silicone polymer, and in cases where the silicone polymer of the third layer 13 is thermally cured on the upper surface 12S1 of the second layer 12, there is a high bonding force between the silicone polymer of the third layer 13 and the silicone polymer of the second layer 12. Alternatively, the third layer 13 has a different color from the second layer 12. For example, the third layer 13 is red or pink, and the second layer 12 is gray or brown. Here, the color distinction between the second and third layers 12 and 13 helps determine the mounting position of the sheet 1. According to an embodiment, the sheet 1 includes a double-sided tape that is attached to the upper surface 13S1 of the third layer 13. The double-sided tape has a thermal conductivity.

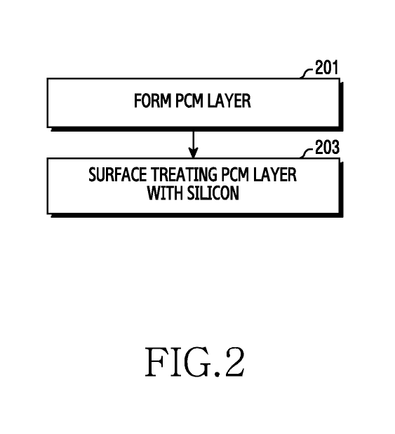

FIG. 2 illustrates an example procedure of manufacturing a sheet according to this disclosure. Referring to FIG. 2, a Phase Change Material (PCM) layer (such as the second layer 12 of FIG. 1) is formed in step 201. For example, the phase change material layer is formed using such a manner of changing a solid phase change material (such as PCM25) into the liquid phase and then solidifying the liquid phase change material on the surface of a plastic film, for example a Polyethyleneterephtalate (PET) film, (such as the first layer 11 of FIG. 1). In step 203, a silicon layer (such as the third layer 13 of FIG. 1) is formed in such a manner that the phase change material layer is subjected to surface treatment using silicon or silicone polymer.

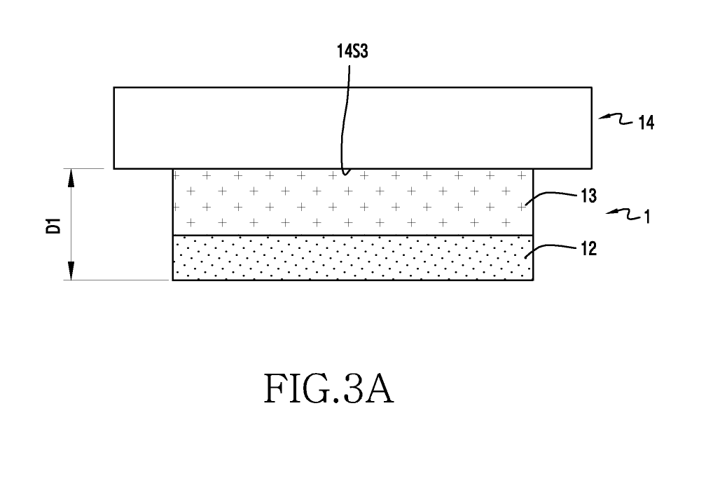

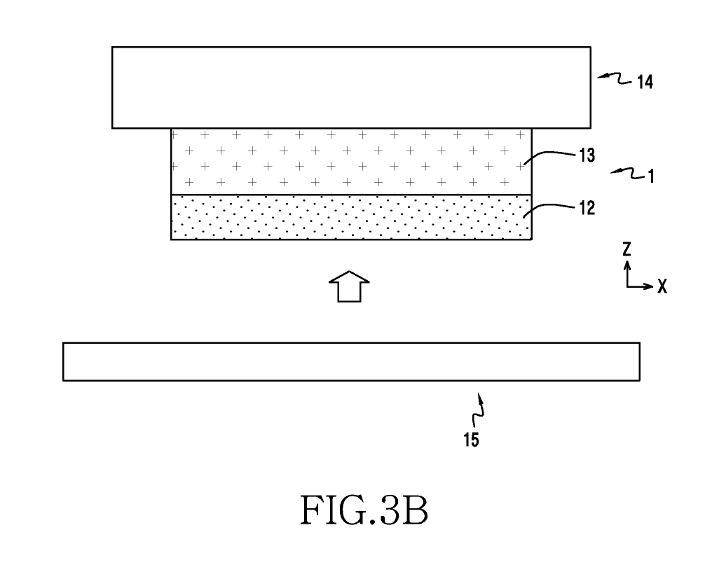

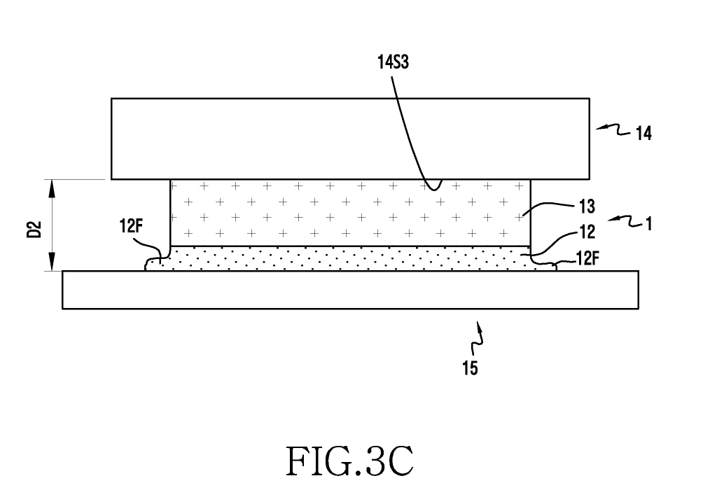

FIGS. 3A, 3B, and 3C illustrate example processes for sheet mounting according to this disclosure. The sheet 1 of FIG. 1, from which the first layer 11 is separated, is used. Referring to FIG. 3A, the sheet 1 is disposed on at least a portion of the lower surface 14S3 of a heating element 14 (such as an electronic component releasing heat). The third layer 13 of the sheet 1 is disposed between the heating element 14 and the second layer 12. An adhesive unit (or a viscous material) may not he interposed between the third layer 13 of the sheet 1 and the lower surface 14S3 of the heating element 14. Alternatively, an adhesive unit is interposed between the third layer 13 of the sheet 1 and the lower surface 14S3 of the heating element 14. However, the adhesive force thereof is weak. The third layer 13 of the sheet 1 is easily separated from the heating element 14.

Referring to FIGS. 3B and 3C, the sheet 1 is disposed between the heating element 14 and a heat dissipation plate 15. The heating element 14 is attached to a board (such as a Printed Circuit Board (PCB)), and the board and the heat dissipation plate 15 (such as a device case or a bracket) is coupled to each other (such as fastened to each other with bolts).

The gap D2 between the heating element 14 and the heat dissipation plate 15 is smaller than the thickness (such as D1 in FIG. 3A) of the sheet 1. The sheet 1 is subjected to pressure from the heating element 14 and the heat dissipation plate 15 and have a repulsive three (such as resilient force) against the pressure. Although the sheet 1 is brought close to the heating element 14 and the heat dissipation plate 15, the sheet 1 is unstable due to the pressure consistently applied thereto. The heating element 14 and the heat dissipation plate 15 is a rigid body that is not elastically deformed, and thus a considerably large pressure is applied to the sheet 1. Alternatively, the heating element 14 or the heat dissipation plate 15 is elastically deformed (deflected) to reduce the pressure applied to the sheet 1. However, since the heating element 14 or the heat dissipation plate 15 is deformed in this case, it may not be desirable.

According to an embodiment for stably disposing the sheet 1 between the heating element 14 and the heat dissipation plate 115, the second layer 12 of the sheet 1 is deformed by the pressure between the heating element 14 and the heat dissipation plate 15 and the heat released from the heating element 14, and the thickness of the sheet 1 is consequently reduced. The sheet 1 is stably disposed between the heating element 14 and the heat dissipation plate 15 due to the deformation of the second layer 12, The second layer 12 of the sheet 1 contains a thermoplastic material that is changed from the solid phase into liquid fluid 12F by the heat between the heating element 14 and the heat dissipation plate 15. For example, the second layer 12 of the sheet 1 contains a phase change material that is changed from the solid phase into the liquid phase by heat.

The heating element 14 generates heat, and the heat is transferred to the heat dissipation plate 15 through the sheet 1. Here, the material of the second layer 12 is changed from the solid phase into the liquid phase by heat. Such liquid fluid 12F flows under the pressure between the third layer 13 and the heat dissipation plate 15 and resolve the pressure between the third layer 13 and the heat dissipation plate 15. The thickness of the liquid fluid 12F between the third layer 113 and the heat dissipation plate 15 becomes smaller than the initial thickness of the second layer 12. In cases where the amount of the liquid fluid 12F is considerable, the liquid fluid 12F also flows outward departing from the space between the third layer 13 and the heat dissipation plate 15. According to an embodiment, the heat dissipation plate 15 is preheated, and the second layer 12 of the sheet 1 is deformed by the heat from the heat dissipation plate 15 in the process of coupling the heat dissipation plate 15 and the heating element 14. The heat dissipation plate 15 diffuses the heat generated from the heating element 14. The heat dissipation plate 15 prevents the heating element 14 from being heated.

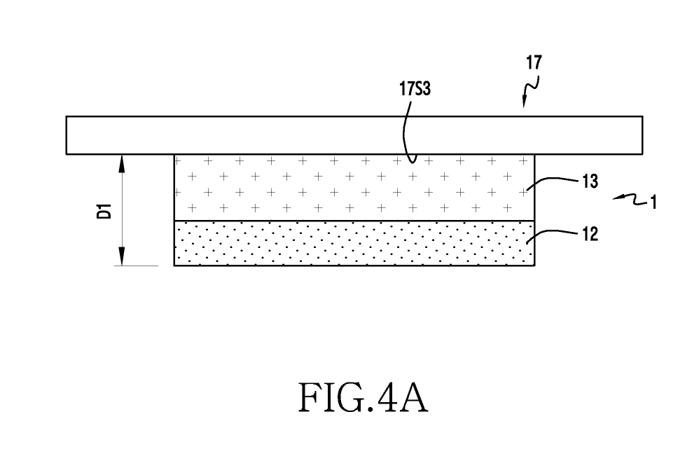

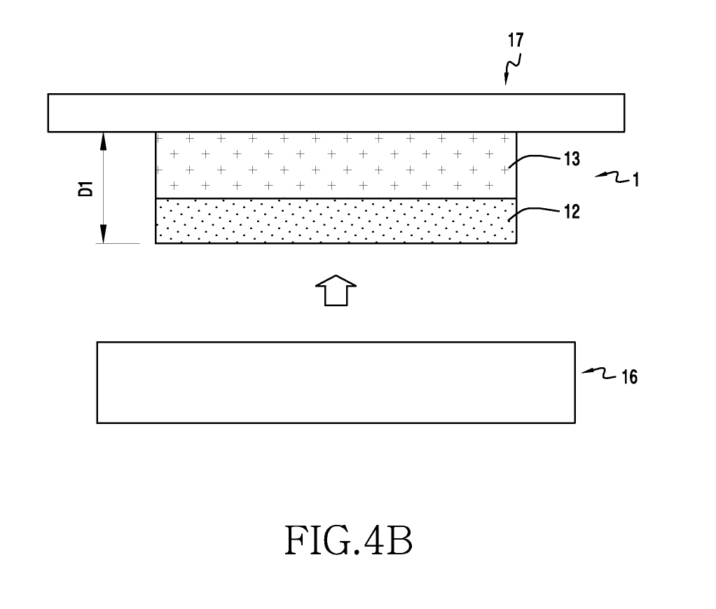

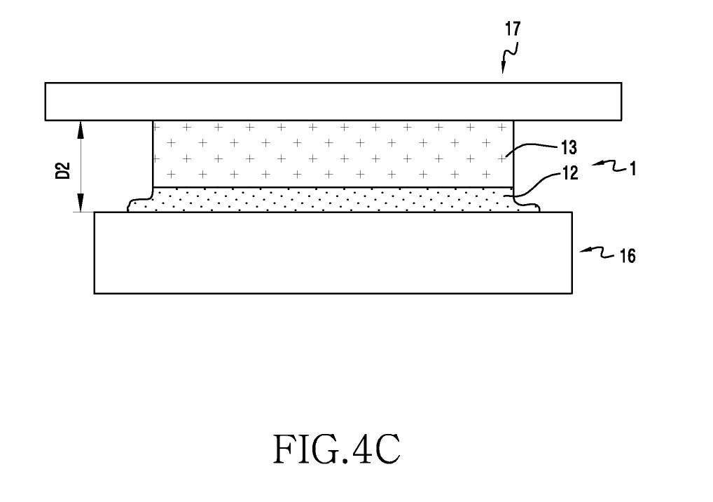

FIGS. 4A, 4B, and 4C illustrate example processes for sheet mounting according to this disclosure. Referring to FIG. 4A, the sheet 1 is attached to at least a portion of the lower surface 17S3 of a heat dissipation plate 17. The third layer 13 of the sheet 1 is disposed between the heat dissipation plate 17 and the second layer 12.

Referring to FIGS. 4B and 4C, the sheet 1 is disposed between a heating element 16 and the heat dissipation plate 17. The gap D2 between the heating element 16 and the heat dissipation plate 17 is smaller than the thickness (such as D1 in FIG. 4A) of the sheet 1. The sheet 1 is subjected to pressure from the heating element 16 and the heat dissipation plate 17 and have a repulsive force (such as resilient force) against the pressure. Although the sheet 1 is brought close to the heating element 16 and the heat dissipation plate 17, the sheet 1 is unstable due to the pressure consistently applied thereto. As described herein, the second layer 12 of the sheet 1 is deformed by the pressure between the heating element 16 and the heat dissipation plate 17 and the heat released from the heating element 16, and the thickness of the sheet 1 is consequently reduced. Therefore, the sheet 1 is stably disposed between the heating element 16 and the heat dissipation plate 17 due to the deformation of the second layer 12.

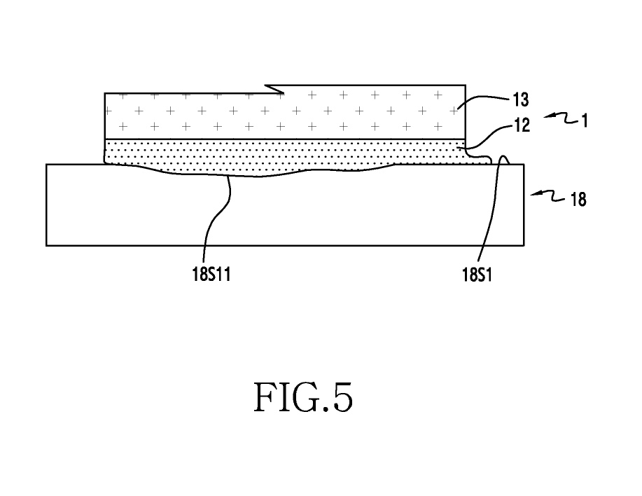

FIG. 5 illustrates an example use of a sheet according to this disclosure. Referring to FIG. 5, the sheet 1 is disposed on the upper surface 18S1 of a mounting plate 18 (such as the heating element 14 or the heat dissipation plate 15). The upper surface 18S1 of the mounting plate 18 includes an uneven surface 18S 11. According to an embodiment, the material of the second layer 12 of the sheet 1 is changed from the solid phase into the liquid phase by heat from the mounting plate 18, and the liquid fluid flows toward (or fills) the uneven surface 18S11 of the mounting plate 18. The space or air layer between the liquid fluid and the uneven surface 18S11 decreases, thereby improving the amount of heat transferred between the sheet I and the mounting plate 18.

Here, even though the gap between the heating element (such as reference numeral 14 of FIG. 1) and the heat dissipation plate (reference numeral 15 of FIG. 1) is smaller than a preset one, the thermoplastic material (such as the second layer 12) of the sheet 1 is changed into the liquid fluid by the heat from the heating element 14, and the liquid fluid flows to resolve the pressure between the heating element and the heat dissipation plate.

According to an embodiment, a Thermal Interface Material (TIM) (or, simply an interface member or a heat transfer member) is intentionally prepared to be thicker than the gap between the heating element (reference numeral 14 of FIG. 1) and the heat dissipation plate (reference numeral 15 of FIG. 1). For example, in cases where an integrated circuit chip is mounted on a substrate using Surface Mounting Technology (SMT), the integrated circuit chip is disposed closer to the substrate as the thickness of a solder becomes smaller. Considering this point, the thermal interface material is processed in advance to be thick. The above-described sheet 1 is used as the thermal interface material and mounted according to the process of FIGS. 3A and 3B or FIGS. 4A and 4B.

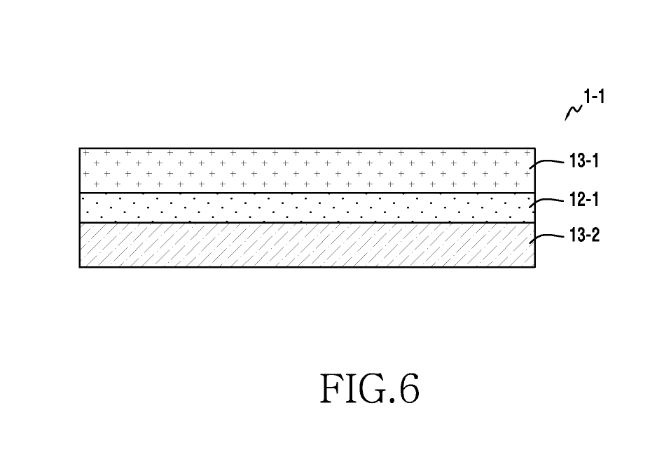

FIG. 6 illustrates an example sheet according to this disclosure. Referring to FIG. 6, a sheet 1-1 includes first to third layers 13-1, 12-1, and 13-2 having a thermal conductivity. The second layer 12-1 is interposed between the first and third layers 13-1 and 13-2. According to an embodiment, the second layer 12-1 contains a material that is changed from the solid phase into the liquid phase by heat. The second layer 12-1 (such as the second layer 12) is deformed due to the flow of liquid fluid, and accordingly the sheet 1-1 is stably disposed between thermal conductors (such as the heating element 14 and the heat dissipation plate 15) (see FIGS. 3A and 3B). The first layer 13-1 or the third layer 13-2 contains a resilient material. According to an embodiment, the first layer 13-1 and the third layer 13-2 contains different materials.

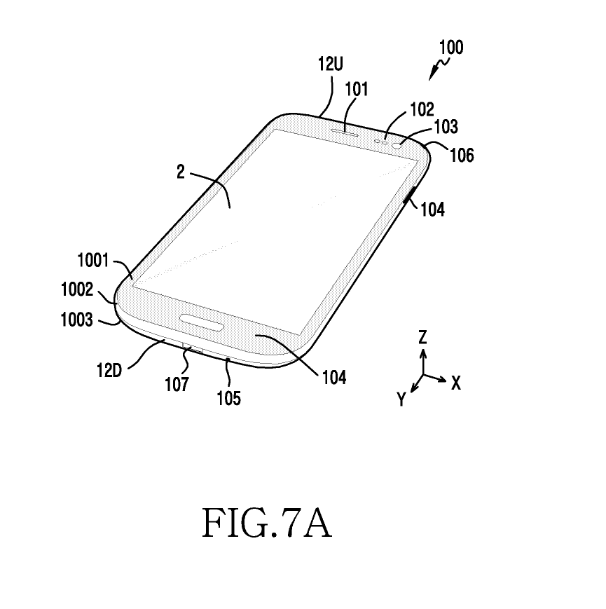

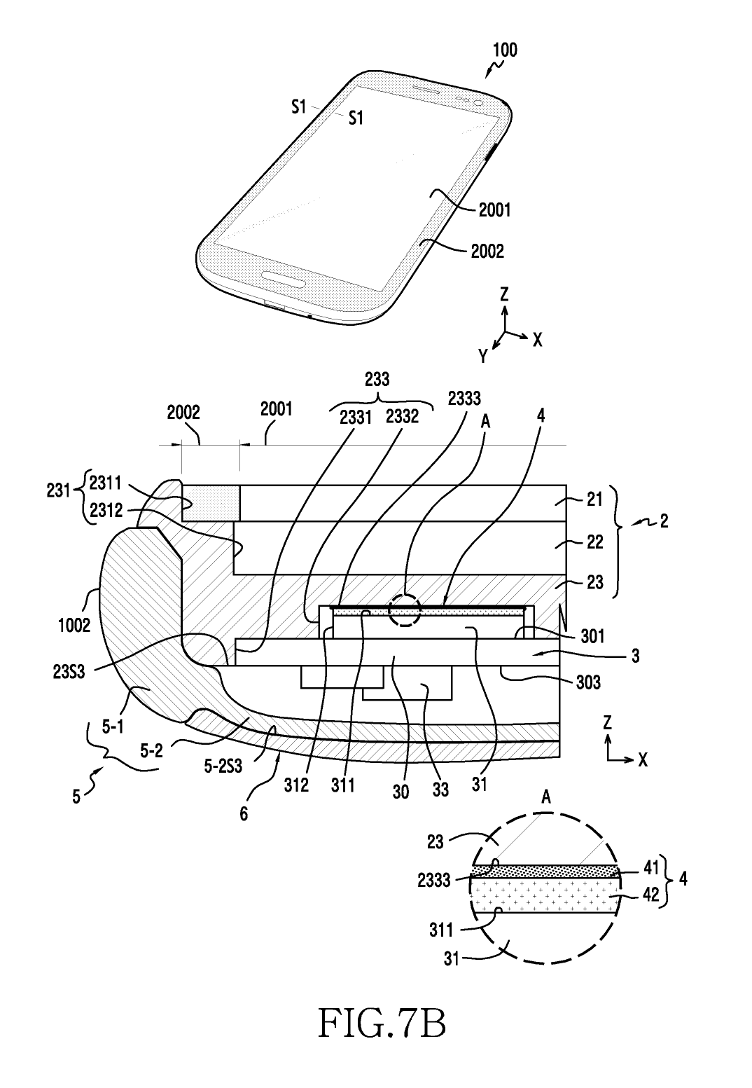

FIG. 7A illustrates an example electronic device according to this disclosure. Referring to FIG. 7A, an electronic device 100 includes the upper surface 1001, the side surface 1002, and the lower surface 1003. The side surface 1002 interconnects the upper and lower surfaces 1001 and 1003. The upper surface 1001, the side surface 1002, or the lower surface 1003 includes a flat surface or a curved surface. For example, the electronic device 100 includes the upper or lower surface 1001 or 1003 in the shape of a convex or concave curved surface. Alternatively, the electronic device 100 also has the upper surface 1001, the side surface 1002, or the lower surface 1003 which is flexible or wearable to be deformed.

The electronic device 100 includes a display set 2, a speaker 101, a sensor 102, a camera 103, a button 104, a microphone 105, an antenna 106, or a socket 107. The display set 2 is disposed on the upper surface 1001 of the electronic device 100. The display set 2 include a Liquid Crystal Display (LCD), an Active Matrix Organic Light Emitting Diode (AM-OLED), or the like. Alternatively, the display set 2 also includes a touch detection device (such as a touch panel or a digitizer) that recognizes a touch input. The speaker 101 is disposed on the upper surface 1001 of the electronic device 100. Alternatively, the speaker 101 is also disposed on the side surface 1002 or the lower surface 1003 of the electronic device 100.

The sensor 102 is disposed on the upper surface 1001 of the electronic device 100 but however, is not limited thereto. The sensor 102 measures a physical quantity or senses an operating state of the electronic device 100 and converts the measured or sensed information into an electric signal. Such a sensor 102 includes a gesture sensor, a proximity sensor, a grip sensor, a gyro sensor, an acceleration sensor, a terrestrial magnetism sensor, an atmospheric sensor, a temperature/humidity sensor, a Hall sensor, a Red/Green/Blue (RGB) sensor, an illumination sensor, a bio-sensor (such as a heart rate sensor), an Ultra Violet (UV) sensor, or the like.

The camera 103 is disposed on the upper surface 1001 of the electronic device 100 as illustrated but however, is not limited thereto. The button 104 is disposed on the upper surface 1001 or the side surface 1002 of the electronic device 100 as illustrated but however, is not limited thereto. A press type button or a touch type button is employed for the button 104. The microphone 105 is disposed on the side surface 1002 of the electronic device 100. Alternatively, the microphone 105 is also disposed on the upper surface 1001 or the lower surface 1003 of the electronic device 100.

The antenna 106 (such as a Digital Multimedia Broadcasting (DMB) antenna, a cellular antenna, or the like) is extracted and extended to the outside through a though-hole formed in the side surface 1002 of the electronic device 100. Alternatively, the antenna 106 is also an embedded antenna mounted to the housing, a case frame, or a circuit board (such as a main board) of the electronic device 100.

The socket 107 is disposed on the side surface 1002 of the electronic device 100 as illustrated but however, is not limited thereto. The socket 107 (such as a USB socket, a charging jack, a communication jack, or the like) is disposed on the lower section 12D of the side surface 1002. In addition, a socket (such as an earphone jack) is disposed on the upper section 12U of the side surface 1002. Such a socket 107 is an interface device to which a plug of an external device (such as an ear-set, a charger, or the like) is connected, and employs a communication scheme such as High-Definition Multimedia Interface (HDMI), Universal Serial Bus (USB), projector, D-subminiature (D-sub), or the like. Furthermore, the electronic device 100 further includes a stylus. The stylus is extracted to the outside through a through-hole formed in the side surface 1002 of the electronic device 100.

FIG. 7B is a sectional view of an example electronic device according to this disclosure. Referring to FIG. 7B, the electronic device 100 includes the display set 2, a Printed Board Assembly (PBA) 3, a heat interface material 4, a device case 5, or a cover 6. The display set 2 includes a window 21, a display 22, and a bracket 23. The window 21 includes a transparent plate, a bonding layer, a plastic film, a pattern layer, a metal layer, or a light shielding layer. The transparent plate is disposed above the display 22 to protect the display 22. The transparent plate is molded of plastic, such as acrylic, having impact resistance or glass (such as reinforced glass).

The bonding layer is disposed between the transparent plate and the plastic film, and bonds the plastic film to the transparent plate. The bonding layer is disposed in the peripheral area 2002, having a thickness or distance S1 spanning from a view area 2001 to the edge of the electronic device 100, (such as the rectangular annular area) of the window 21. The bonding layer may not overlap with the view area 2001. Here, the view area 2001 indicates an area where images of the display 22 are displayed and is referred to as a ‘display area.’ The bonding layer is transparent. Alternatively, the bonding layer is also dyed using dye, pigment, coloring matter, fluorescent material, phosphor, or the like that forms a particular color, The bonding layer includes a Pressure Sensitive Adhesive (PSA).

The plastic film is attached to the peripheral area 2002 of the window 21 by the bonding layer. The plastic film has a band shape corresponding to the peripheral area 2002 of the window 21. The plastic film may not overlap with the view area 2001. The plastic film is transparent. The plastic film is molded of a material having high thermal stability and high mechanical strength. The plastic film is a Polyethyleneterephthalate (PET) film, a Polycarbonate (PC) film, a Polyethylene (PE) film, a Polypropylene (PP) film, or the like.

The pattern layer is attached to the lower surface of the plastic film or includes various printed patterns (such as a plane pattern or a 3D pattern). The pattern layer may not overlap with the view area 2001. The pattern layer is molded through Ultra Violet (UV) molding. The pattern layer molded through UV molding has a pattern corresponding to that formed in a mold. The pattern of the mold is formed through mechanical working, laser processing, photolithography, or the like. The pattern layer reflects external light and express a metal texture. The pattern of the pattern layer is a hairline. Since the pattern layer is disposed below the transparent plate having a predetermined thickness, the pattern of the pattern layer is shown in three dimensions through the transparent plate.

The metal layer is attached to the lower surface of the pattern layer. The metal layer may not overlap with the view area 2001. The metal layer is formed in such a manner of depositing (such as Physical Vapor Deposition (PVD) or Chemical Vapor Deposition (CVD)) or coating metal (such as Sn, Al, Si, Ti, TiC, TiN, TiCB, Al₂O₃, or the like) on the lower surface of the pattern layer. The metal layer reflects external light and express a metal texture. Since the metal layer is disposed below the transparent plate having a predetermined thickness, the pattern of the metal layer is shown in three dimensions through the transparent plate. A portion of the transparent plate that does not correspond to the view area 2001 expresses a metal texture due to the pattern layer and the metal layer.

The light shielding layer is formed on the lower surface of the metal layer. The light shielding layer may not overlap with the view area 2001. The light shielding layer shields external light emitted to the peripheral area of the transparent plate. The light shielding layer prevents light from the display 22 from being emitted to the peripheral area of the transparent plate. The light shielding layer includes a black component that absorbs light rather than reflects the light. The light shielding layer is a black printed layer. The light shielding layer is an adhesive containing a black component. The light shielding layer includes a black film and an adhesive material.

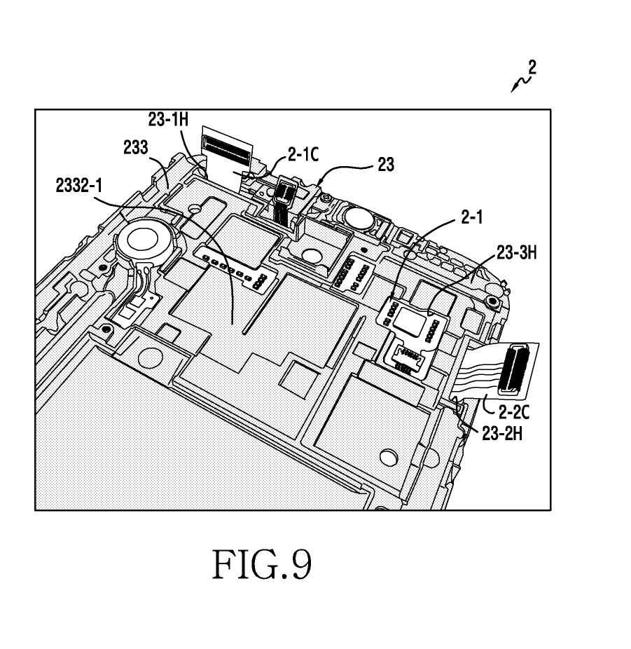

The display 22 is disposed below the window 21. Here, the display 22 is attached to the transparent bonding layer and disposed below the light shielding layer. The display 22 includes a display panel. For example, the display panel is a Liquid Crystal Display (LCD), an Active Matrix Organic Light Emitting Diode (AM-OLED), or the like. The display 22. is implemented to be flexible, transparent, or wearable. Here, the window 21 also be implemented to be flexible or wearable. In addition, the display set 2 further includes a circuit board (such as reference numeral 2-1 of FIG. 9). The circuit board is disposed below the display panel. The PBA 3 controls images through the display 22 using the circuit board.

The display set 2 further includes a touch panel. The touch panel (such as a capacitive type touch panel, a resistive type touch panel, or the like) is disposed between the window 21 and the display 22. In addition, the display set 2 further includes a non-illustrated. digitizer panel The digitizer panel is disposed below the display panel. Here, the view area 2001 where a touch input is made using the touch panel or the digitizer panel is referred to as a ‘touch input area.’ The PBA 3 senses a touch input through the touch panel or the digitizer panel using the above-described circuit board. The bracket 23 includes a mounting plate on which a plurality of electronic components is mounted. The bracket 23 includes an upper mounting part 231 and a lower mounting part 233.

The upper mounting part 231 is a part where the window 21 and the display 22 are disposed, and includes at least a portion of the upper surface of the bracket 23. The upper mounting part 231 has various shapes including a flat surface and/or a curved surface. For example, the upper mounting part 231 has a shape in which the upper side thereof is open. The window 21 is disposed on the upper side 2311 (such as an upper opening portion) of the upper mounting part 231 and the display 22 is disposed on the lower side 2312 of the upper mounting part 231. According to an embodiment, the window 21 and the display 22 is attached to the upper mounting part 231 of the bracket 23 using an adhesive.

The lower mounting part 233 is a part where the PBA 3 is disposed, and includes at least a portion of the lower surface 23S3 of the bracket 23. The lower mounting part 233 has various shapes including a flat surface and/or a curved surface. The lower mounting part 233 includes a substrate disposition part 2331 and a substrate-mounted component disposition part 2332. The substrate disposition part 2331 is a part where a substrate 30 of the PBA 3 is disposed. The substrate disposition part 2331 includes a boss. The substrate 30 is secured to the substrate disposition part 2331 through fastening bolts. The substrate-mounted component disposition part 2332 is a part where an electronic component 31 protruding from the upper surface 301 of the substrate 30 is disposed.

The bracket 23 provides rigidity to the display set 2. In addition, the bracket 23 also shields electrical noise. Furthermore, the bracket 23 includes a heat dissipation plate (such as the heat dissipation plate 15 of FIG. 3C) for preventing an electronic component from being heated. Here, the bracket 23 diffuse heat from the display 22 or the PBA 3. According to an embodiment, the bracket 23 contains a metal material (such as Mg, Al, or the like). The bracket 23 is molded using various means such as die casting, Computerized Numerical Control (CNC), and the like. The PBA 3 includes a circuit board, a main board, or a mother board. The PBA 3 sets an execution environment of the electronic device 100, maintain the setting information, and allow the electronic device 100 to be stably driven. In addition, the PBA 3 allows all devices of the electronic device 100 to effectively perform data input/output exchange.

The PBA 3 is disposed between the display set 2 and the device case 5. For example, the PBA 3 is disposed in the lower mounting part 233 of the bracket 23. The PBA 3 includes the substrate 30, the substrate-upper-side mounted component 31, and a substrate-lower-side mounted component 33. The substrate 30 includes a plate in which an electrical circuit is formed. The upper surface 301 of the substrate 30 makes contact with at least a portion of the lower surface 2353 of the bracket 23. The lower surface 303 of the substrate 30 faces the device case 5. The substrate-upper-side mounted component 31 protrudes upward from the upper surface 301 of the substrate 30 and is disposed in the substrate-mounted component disposition part 2332 of the bracket 23. The substrate-lower-side mounted component 33 protrudes downward from the lower surface 303 of the substrate 30. The substrate-upper-side mounted component 31 and/or the substrate-lower-side mounted component 33 are of a Surface Mount Device (SMD) type or a Dual In line Package (DIP) type.

The thermal interface material 4 is disposed between the PBA 3 and the bracket 23. The thermal interface material 4 transfers heat generated from the PBA 3 (such as the substrate-upper-side mounted component 31) to the bracket 23. For example, the thermal interface material 4 is disposed between the substrate-upper-side mounted component 31 (such as an integrated circuit chip) and the bracket 23. The thermal interface material 4, as illustrated, is disposed between the upper surface 311 of the substrate-upper-side mounted component 31 and one surface 2333 of the bracket 23 that face each other. Here, the gap between the upper surface 311 of the substrate-upper-side mounted component 31 and the surface 2333 of the bracket 23 may or may not be constant. Alternatively, the thermal interface material 4 is disposed between a side surface 312 of the substrate-upper-side mounted component 31 and one surface of the bracket 23 that face each other.

According to an embodiment, the thermal interface material 4 includes multiple layers. The multiple layers has the same or different materials. The multiple layers have at least one same or different physical property (such as an electrical, magnetic, optical, thermal, mechanical, or chemical property). In addition, the multiple layers have the same or different thicknesses. For example, the thermal interface material 4 includes an upper layer 41 and a lower layer 42. The upper layer 41 is disposed on the surface 2333 of the bracket 23, and the lower layer 42 is disposed on the surface 311 of the substrate-upper-side mounted component 31. The thermal interface material 4 includes the sheet 1 of FIG. 1. For example, among the upper and lower layers 41 and 42, one contains a Phase Change Material (PCM) and the other contains a resilient conductive material (such as silicone polymer). The upper layer 41 has a different color from the lower layer 42, and the color distinction helps identify the mounting position of the thermal interface material 4.

According to an embodiment, the thermal interface material 4 follows the mounting procedure for the sheet 1 illustrated in FIGS. 3A to 3C. Here, the PBA 3 for the substrate-upper-side mounted component 31) includes the heating element 14 of FIG. 3C, and the bracket 23 includes the heat dissipation plate 15 of FIG, 3C. According to an embodiment, the thermal interface material 4 also follows the mounting procedure for the sheet 1 illustrated in FIGS. 4A to 4C. Here, the PBA 3 includes the heating element 16 of FIG. 4C, and the bracket 23 includes the heat dissipation plate 17 of FIG. 4C. The display set 2 (such as the display 22 and the circuit board) generates heat, and the generated heat is transferred to the bracket 23. Here, the phase change material of the thermal interface material 4 is changed into liquid fluid not only by heat from the PBA 3 but also by heat of the bracket 23 (such as heat transferred from the display set 2). The device case 5 includes a first case body 5-1 and a second case body 5-2.

The first case body 5-1 is a part where the display set 2 is mounted, and includes the side surface 1002 of the electronic device 100. The first case body 5-1 is fastened to the bracket 23 of the display set 2 with bolts. The second case body 5-2 extends from the first case body 5-1 and is disposed between the PBA 3 and the cover 6. The second case body 5-2 includes, on the lower surface 5-2S3 thereof, a part where the cover 6 is mounted. The cover 6 is easily attached to and detached from the second case body 5-2. For example, the cover 6 includes a plurality of non-illustrated hooks arranged on the periphery thereof, and the second case body 5-2 includes a plurality of hook fastening recesses to which the plurality of hooks of the cover 6 are fastened. Here, the method in which the plurality of hooks of the cover 6 and the plurality of hook fastening recesses of the second case body 5-2 are fastened to each other is referred to as a snap-fit fastening method. In addition, the second case body 5-2 also includes a non-illustrated support shape for supporting the lower surface 303 of the PBA 3. Furthermore, the second case body 5-2 is fastened to the display set 2 with bolts.

The cover 6 includes the lower surface (reference numeral 1003 of FIG. 7A) of the electronic device 100. The cover 6 is separated from the device case 5 when a detachable electronic component (such as a memory card, a battery pack, or the like) is replaced. The cover 6 is referred to as a ‘battery cover.’ The exposed surface (the lower surface 1003 of the electronic device 100) of the cover 6 includes a curved surface. The exposed surface of the cover 6 is smoothly connected to the exposed surface of the device case 5 (the side surface 1002 of the electronic device 100) to make the outer surface of the electronic device 100 appealing. A combination of the bracket 23, the device case 5, and the cover 6 is referred to as a ‘housing’ or ‘case frame.’

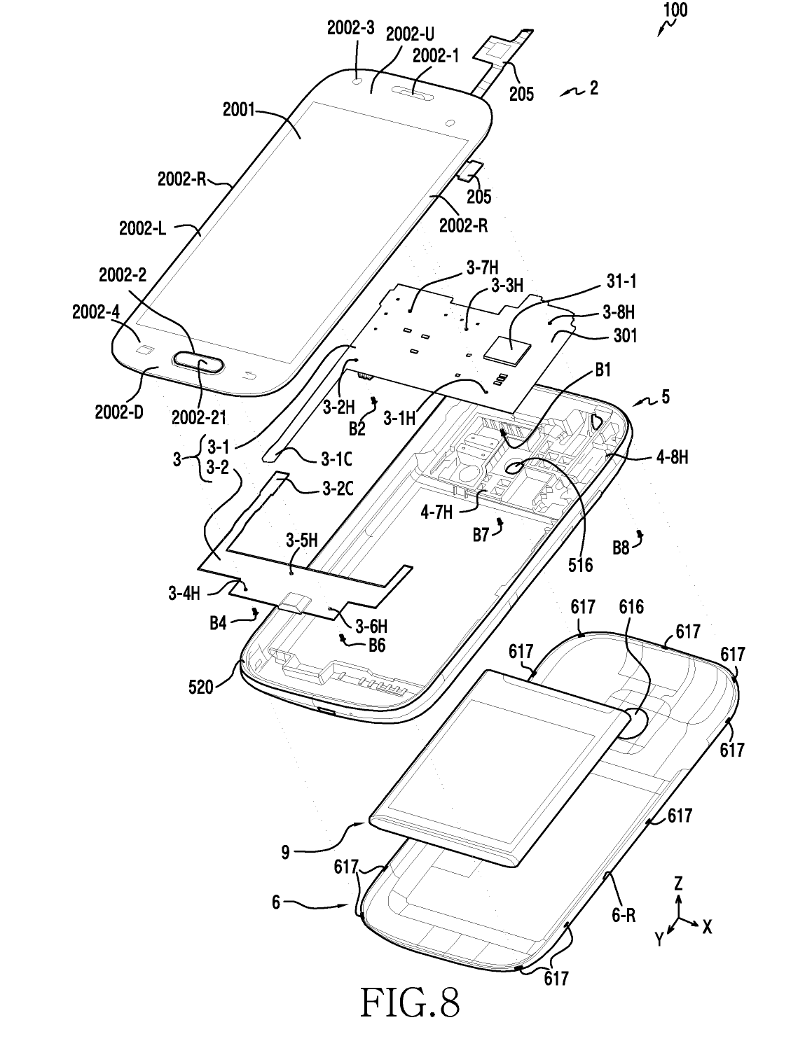

FIG. 8 is an exploded perspective view of an example electronic device according to this disclosure. Referring to FIG. 8, the electronic device 100 includes the display set 2, the PBA 3, the device case 5, a battery pack 9, or the cover 6. The display set 2 generally has a quadrangular (such as rectangular) flat plate shape. The display set 2 includes a display area 2001 and a non-display area 2002. The display area 2001 corresponds to an image displayable area, namely a screen, of the display (reference numeral 22 of FIG. 7B). The display area 2001 has a rectangular shape extending in the Y-axis direction. The non-display area 2002 (such as the peripheral area 2002 of FIG. 7B) surrounds the display area 2001 and has an annular shape. For example, the non-display area 2002 includes an upper peripheral area 2002-U, a lower peripheral area 2002-D, a left peripheral area 2002-L, and a right peripheral area 2002-R. The upper and lower peripheral areas 2002-U and 2002-D is disposed to face each other. In addition, the left and right peripheral areas 2002-L and 2002-R are disposed to face each other. The upper and lower peripheral areas 2002-U and 2002-D have a larger width than the left and right peripheral areas 2002-L and 2002-R. The non-display area 2002 is represented in black. Alternatively, the non-display area 2002 also has a metal texture.

The display set 2 has a receiver hole 2002-1 formed in the non-display area 2002 (such as the upper peripheral area 2002-U). The receiver hole 2002-1 is positioned to correspond to a receiver mounted to the PBA 3 or the device case 5, and a sound output from the receiver comes out through the receiver hole 2002-1. The display set 2 has a button hole 2002-2 formed in the non-display area 2002 (such as the lower peripheral area 2002-D). The display set 2 includes button circuit disposed between the window (reference numeral 21 of FIG. 7B) and the bracket (reference numeral 23 of FIG. 7B). A button 2002-21 of the button circuit is disposed on the upper surface (reference numeral 1001 of FIG. 7A) of the electronic device 100 through the button hole 2002-2.

The display set 2 further includes a transparent area 2002-3 disposed in the non-display area 2002. The transparent area 2002-3 is disposed to correspond to a sensor (such as an illumination sensor, an image sensor, or the like) mounted on the PBA 3. The display set 2 further includes touch key markers 2002-4 disposed in the non-display area 2002. The touch key markers 2002-4 is disposed on the opposite sides of the button hole 2002-2. The display set 2 includes a touch key circuit disposed between the window 21 and the bracket 23. The touch key circuit is disposed to correspond to the touch key markers 2002-4.

The display set 2 includes an electric connection unit 205. The electric connection unit 205 is used to electrically connect the display (reference numeral 22 of FIG. 7B) mounted on the display set 2 or a non-illustrated touch key device (such as a touch panel or a digitizer) and the PBA 3. Alternatively, the electric connection unit 205 is used to electrically connect the non-illustrated button circuit or touch key circuit mounted to the display set 2 and the PBA 3.

The electric connection unit 205 includes a connector (such as a male or female connector) that is connected to a connector of the PBA 3. The electric connection unit 205 is implemented to be bendable and connected to a connector mounted on the lower surface (reference numeral 303 of FIG. 79) of the PBA 3. For example, the electric connection unit 205 includes a Flexible Printed Circuit Board (FPCB) or a cable.

The PBA 3 is disposed between the display set 2 and the device case 5. The PBA 3 is mounted on the bracket (reference numeral 23 of FIG. 7B) of the display set 2. The PBA 3 includes an Application Processor (AP) 31-1 (such as the substrate-upper-side mounted component 31) disposed on the upper surface 301 thereof The AP 31-1 controls a plurality of hardware or software elements by driving an operating system or an application program, and performs data processing and calculations on various types of data including multimedia data. The AP 31-1 is implemented as, for example, a System on a Chip (SoC). The AP 31-1 further includes a Graphic Processing Unit (GPU).

According to an embodiment, the thermal interface material (reference numeral 4 of FIG. 7B) is disposed between the AP 31-1 and the bracket 23 of the display set 2. Heat generated from the AP 31-1 is transferred to the bracket 23 through the thermal interface material, thereby preventing the AP 31-1 from being heated. The PBA 3 includes a plurality of removable circuit boards 3-1 and 3-2. For example, the PBA 3 includes the first circuit board 3-1 and the second circuit board 3-2 that are disposed on the opposite sides of the electronic device 100. The first circuit board 3-1 includes a first connector 3-1C disposed in the peripheral area of the lower mounting part (reference numeral 233 of FIG. 7B) of the bracket 23. The first connector 3-1C has a shape relatively protruding and extending from the remaining portion of the first circuit board 31. In addition, the second circuit board 3-2 includes a second connector 3-2C disposed in the peripheral area of the lower mounting part (reference numeral 233 of FIG. 7B) of the bracket 23. The second connector 3-2C has a shape relatively protruding and extending from the remaining portion of the second circuit board 3-2. The first and second connectors 3-1C and 3-2C is engaged with each other, and the first and second circuit boards 3-1 and 3-2 is electrically connected to each other.

The PBA 3 has a plurality of bolt holes 3-1H, 3-2H, 3-3H, 3-4H, 3-5H, 3-6H, 3-7H, and 3-8H formed therein. The plurality of bolt holes 3-1H, 3-2H, 3-3H, 3-4H, 3-5H, 3-6H, 3-7H, and 3-8H is disposed to correspond to a plurality of bosses of the bracket 23. A plurality of bolts B1, B2, B3, B4, B5, and B6 passes through the plurality of bolt holes 3-1H, 3-2H, 3-3H, 3-4H, 3-5H, and 3-6H and is fastened to the plurality of bosses of the bracket 23 so that the PBA 3 and the bracket 23 is coupled together. The device case 5 has a plurality of bolt holes 4-7H and 4-8H formed therein. The plurality of bolt holes 4-7H and 4-8H is disposed to correspond to the plurality of bolt holes 3-7H and 3-8H. A plurality of bolts B7 and B8 passes through the plurality of bolt holes 4-7H and 4-8H of the device case 5 and the plurality of bolt holes 3-7H and 3-8H of the PBA 3 and is fastened to the plurality of bosses of the bracket 23 so that the device case 5, the PBA 3, and the bracket 23 is coupled together.

Through the bolt fastening, the PBA 3 is coupled to the bracket 23, and the gap (such as reference numeral D2 of FIG. 3C) between the PBA 3 and the bracket 23 is maintained. The device case 5 is disposed below the PBA 3. An upper opening portion 520 of the device case 5 includes a portion where the display set 2 is mounted. The device case 5 contains a conductive material. The conductive material reduces the electrical noise of the electronic device 100. In addition, the conductive material also diffuses heat releasing from a heating element (such as the PBA 3). For example, a thermal interface material (such as the sheet 1 of FIG, 1) is disposed between the PBA 3 and the device case 5. Here, the thermal interface material is mounted according to the mounting procedure illustrated in FIGS. 3A to 3C or FIGS. 4A to 4C.

The device case 5 includes a transparent window 516. For example, the transparent window 516 is disposed to correspond to an optical electronic component (such as a camera module) disposed on the lower surface (reference numeral 303 of FIG. 7B) of the PBA 3. The battery pack 9 is disposed in a battery pack mounting section formed on the lower surface (reference numeral 5-2S3 of FIG. 7B) of the device case 5. The cover 6 is disposed below the device case 5. The cover 6 includes a through-hole 616 and a plurality of hooks 617. The through-hole 616 is disposed to correspond to the transparent window 516 of the device case 5. The plurality of hooks 617 is disposed on the periphery 6-R of the cover 6. The plurality of hooks 617 is fastened to a plurality of hook fastening recesses of the device case 5, and thus the cover 6 is coupled to the device case 5.

The cover 6 contains a conductive material. The conductive material reduces the electrical noise of the electronic device 100. In addition, the conductive material also diffuses heat released from the heating element (such as the PBA 3). The electronic device 100 further includes a circuit device, including an antenna or speaker, disposed between the second circuit board 3-2 and the device case 5. For example, a terminal (such as a resilient terminal) of the circuit device makes electric contact with a terminal disposed on the lower surface of the second circuit board 3-2. The circuit device has a shape in which the antenna or speaker is disposed on a plastic injection-molded object.

FIG. 9 illustrates an example display set according to this disclosure. Referring to FIG. 9, the display set 2 includes a circuit board 2-1, a plurality of connectors 2-1C and 2-2C, and a bracket 23. The circuit board 2-1 relates to the display (reference numeral 22 of FIG. 7B). The circuit board 2-1 is disposed on the upper surface (such as the upper mounting part 231 of FIG. 7B) of the bracket 23. A portion of the circuit board 2-1 is exposed through a through-hole 23-3H of the bracket 23. The plurality of connectors 2-IC and 2-2C is electrically connected to the circuit board 2-1 and extends, passing through through-holes 23-1H and 23-2H.

The bracket 23 includes the upper mounting part (reference numeral 231 of FIG. 7B) and the lower mounting part 233. The upper mounting part 231 is a part where the window (reference numeral 21 of FIG. 7B), the display (reference numeral 22 of FIG, 7B), and the circuit board 2-1 are disposed. The lower mounting part 233 faces at least a portion of the upper surface 301 of the PBA (reference numeral 3 of FIG. 8). For example, the lower mounting part 233 includes a surface 2332-1 facing the AP (reference numeral 31-1 of FIG. 8). The surface 2332-1 includes a flat surface or curved surface. According to an embodiment, a thermal interface material (such as the sheet 1 of FIG. 1) is disposed between the surface 2332-1 of the lower mounting part 233 and the AP 31-1.

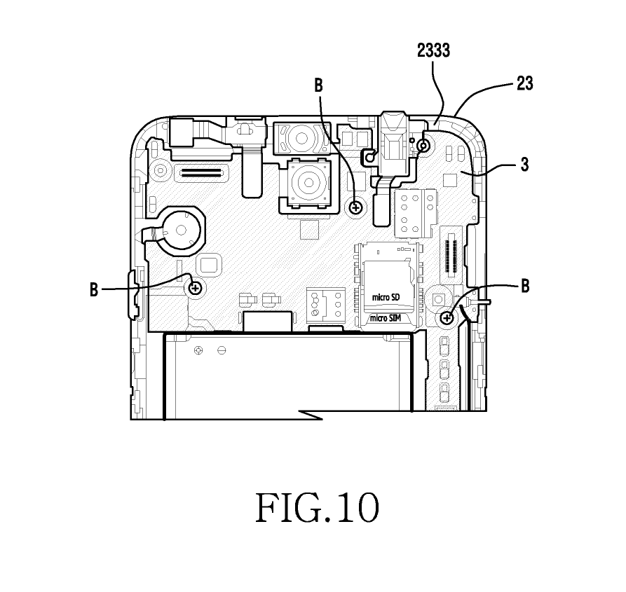

FIG. 10 illustrates a combination between an example display set and an example PBA according to this disclosure. Referring to FIG. 10, the PBA 3 is coupled to the lower surface 23S3 of the bracket 23 using bolts B. The PBA 3 covers at least a portion of the lower surface 23S3 of the bracket 23. A thermal interface material (such as the sheet 1 of FIG. 1) is disposed between the PBA 3 and the bracket 23.

As described herein, the thermal interface material (such as the sheet 1) is changed into liquid fluid by heat from the PBA 3 and/or heat from the bracket 23 (such as heat generated from the display set 2). The liquid fluid flows to resolve the pressure between the PBA 3 and the bracket 23, and the thermal interface material 1 therefore is transformed into a stable form and disposed between the PBA 3 (such as the substrate-upper-side mounted component 31) and the bracket 23. In other words, the thermal interface material 1 is in a stable state where the pressure between the PBA 3 and the bracket 23 is not applied thereto (or a state where the load is not applied thereto). In addition, the PBA 3 and the bracket 23 is disposed in a stable state where the pressure from the thermal interface material 1 is not applied thereto (or a state where the load is not applied thereto).

According to an embodiment, after the AP (reference numeral 31-1 of FIG. 8) is mounted on the substrate 3 using a surface mounting technology, the substrate 3 and the bracket 23 is coupled to each other. Here, the gap between the AP 31-1 and the bracket 23 is smaller than a pre-designed gap (such as a gap designed to appropriately dispose the thermal interface material). In cases where a typical thermal interface material is disposed between the AP 31-1 and the bracket 23, the typical thermal interface material is in an unstable state where the load between the AP 31-1 and the bracket 23 is applied thereto. In the event of a drop or impact, the force caused by the drop or impact is transmitted through the typical thermal interface material to the display (reference numeral 22 of FIG. 7B) (such as an LCD) coupled to the bracket 23, thereby resulting in a black defect indicating a bad pixel of the display 22. Such a black defect causes a problem of having an influence on the flatness of the display 22. In order to solve the problem, the typical thermal interface material is replaced by the thermal interface material (reference numeral 4 of FIG. 7B) according to the embodiment of the present disclosure. Since the thermal interface material 4, according to the embodiment of the present disclosure, contains a Phase Change Material (PCM), even though the gap between the AP 31-1 and the bracket 23 is smaller than a pre-designed gap, the phase change material is changed into a fluid state by heat from the AP 31-1 or the bracket 23 and transformed to be suitable for the gap between the AP 31-1 and the bracket 23. In cases where the gap between the AP 31-1 and the bracket 23 is equal to or larger than the pre-designed gap, the thermal interface material 4 according to the embodiment of the present disclosure maintains the thickness thereof.

The phase change material of the thermal interface material (such as the sheet 1) has a viscosity, and the viscosity increases the adhesive property between the thermal interface material and a thermal conductor. When an impact is applied to the electronic device 100, the thermal interface material (such as the sheet 1) buffers at least a portion of the impact. For example, the third layer 13 (such as the silicon layer) of the thermal interface material 4 is in a state where load is not applied thereto and therefore provides resilience to resist a portion of the impact. The thermal interface material (such as the sheet 1) effectively transfers heat from the PBA 3 (such as the substrate-upper-side mounted component 31) to the bracket 23. For example, as described above with reference to FIG. 5, the phase change material of the thermal interface material 4 is changed into liquid fluid, and the liquid fluid is completely brought close to a corresponding surface (such as the surface 2332-1 of the bracket 23 in FIG. 9), thereby improving the amount of transferred heat.

The thermal interface material (such as the sheet 1) is effective in preventing a substrate-upper-side mounted component (such as reference numeral 31-1 of FIG. 8) from being heated. Therefore, the thermal interface material prevents degradation in the performance of the substrate-upper-side mounted component 31-1. The thermal interface material 4 also reduces the leakage current of the substrate-upper-side mounted component 31-1. Even though the PBA 3 is separated from the bracket 23, the thermal interface material (such as the sheet 1 of FIG. 1) is secure from tearing. For example, referring to FIGS. 3A to 3C, an adhesive unit may not be interposed between the third layer 13 (such as silicon layer) of the sheet 1 and the heating element 14 (such as the substrate-upper-side mounted component 31), and the third layer 13 is separated from the heating element 14 without damage.

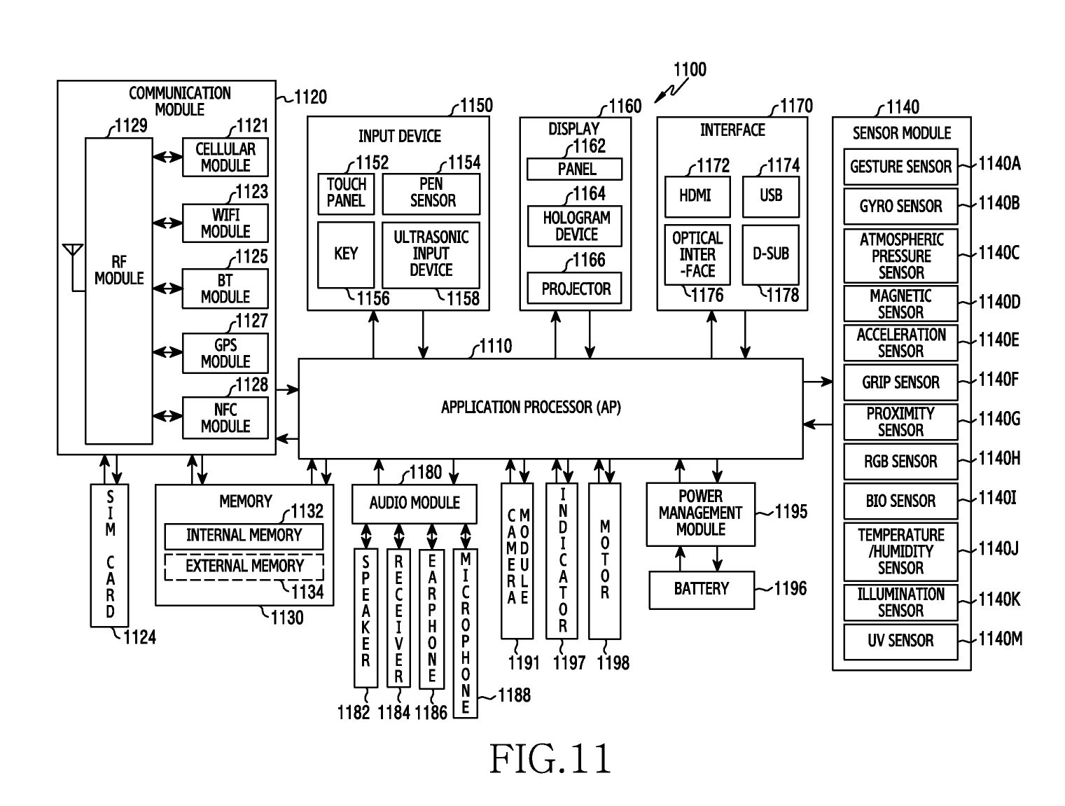

FIG. 11 is a block diagram of an example electronic device according to this disclosure. An electronic device 1100 constitutes, for example, the entirety or a part of the electronic device 100 illustrated in FIG. 7. Referring to FIG. 11, the electronic device 1100 includes one or more Application Processors (APs) 1110, a communication module 1120, a Subscriber Identifier Module (SIM) card 1124, a memory 1130, a sensor module 1140, an input device 1150, a display 1160, an interface 1170, an audio module 1180, a camera module 1191, a power management module 1195, a battery 1196, an indicator 1197, and a motor 1198. The AP 1110 (such as the AP 31-1 of FIG. 8) controls a plurality of hardware or software elements connected thereto by driving an operating system or an application program and perform data processing and calculations on various types of data including multimedia data. The AP 1110 is implemented as, for example, a System on Chip (SoC). According to an embodiment, the AP 1110 further includes a Graphic Processing Unit (GPU).

The communication module 1120 performs data transmission/reception in communication between the electronic device 1100 (such as the electronic device 100 of FIG. 7A) and other electronic devices connected thereto through a network. According to an embodiment, the communication module 1120 includes a cellular module 1121, a WiFi module 1123, a BT module 1125, a (JPS module 1127, an NEC module 1128, and a Radio Frequency (RF) module 1129.

The cellular module 1121 provides a voice call, a video call, a text message service, an Internet service or the like through a communication network (such as Long Term Evolution (LTE), LTE-A, Code Division Multiple Access (CDMA), Wideband CDMA (WCDMA), Universal Mobile Telecommunication System (UMTS), Wireless Broadband (WiBro), Global System for Mobile communication (GSM), or the like). Furthermore, the cellular module 1121 distinguishs between and authenticate electronic devices within a communication network, for example, using a subscriber identification module (such as the SIM card 1124). According to an embodiment, the cellular module 1121 performs at least some of the functions that the processor 1110 provides. For example, the cellular module 1121 performs at least some of the multimedia control functions.

According to an embodiment, the cellular module 1121 includes a Communication Processor (CP). In addition, the cellular module 1121 is implemented as, for example, an SoC. in FIG. 11, the elements such as the cellular module 1121 (such as a communication processor), the memory 1130, and the power management module 1195 are illustrated to be separate from the AP 1110. However, according to an embodiment, the AP 1110 includes at least some of he aforementioned elements (such as the cellular module 1121).

According to an embodiment, the AP 1110 or the cellular module 1121 (such as a communication processor) loads instructions or data, received from at least one of a non-volatile memory and the other elements connected thereto, in a volatile memory and process the loaded instructions or data. In addition, the AP 1110 or the cellular module 1121 stores data received from or generated by at least one of the other elements in a non-volatile memory.

The Wi-Fi module 1123, the BT module 1125, the GPS module 1127, or the NFC module 1128 includes a processor for processing data transmitted/received through the corresponding module. In FIG. 11, the cellular module 1121, the Wi-Fi module 1123, the BT module 1125, the GPS module 1127, and the NEC module 1128 are illustrated as separate blocks. However, according to an embodiment, at least some (such as two or more) of the cellular module 1121, the Wi-Fi module 1123, the BT module 1125, the GPS module 1127, and the NFC module 1128 is included in one integrated chip (IC) or IC package. For example, at least some of the processors corresponding to the cellular module 1121, the Wi-Fi module 1123, the BT module 1125, the GPS module 1127, and the NEC module 1128 (such as a communication processor corresponding to the cellular module 1121 and a Wi-Fi processor corresponding to the Wi-Fi module 1123) is implemented as one SoC.

The RF module 1129 transmits and/or receives data, for example, an RF signal. The RF module 1129 includes, for example, a transceiver, a Power Amp Module (PAM), a frequency filter, a Low Noise Amplifier (LNA), and the like. In addition, the RF module 1129 further includes a component, for example a conductor or conducting wire, for transmitting/receiving electromagnetic waves over free air space in wireless communication. In FIG. 11, the cellular module 1121, the Wi-Fi module 1123, the BT module 1125, the GPS module 1127, and the NEC module 1128 are illustrated to share one RE module 1129. However, according to an embodiment, at least one of the cellular module 1121, the Wi-Fi module 1123, the BT module 1125, the GPS module 1127, and the NEC module 1128 transmit and/or receives an RF signal through a separate RE module.

The SIM card 1124 is a card including a subscriber identification module, and is inserted into a slot formed at a predetermined position of the electronic device. The SIM card 1124 includes unique identification information (such as an integrated circuit card identifier (ICCID)) or subscriber information (such as an international mobile subscriber identity (IMSI)).

The memory 1130 includes an internal memory 1132 and an external memory 1134. The internal memory 1132 includes at least one of, for example, a volatile memory (such as a Dynamic Random Access Memory (DRAM), a Static RAM (SRAM), a Synchronous Dynamic RAM (SDRAM), or the like) or a non-volatile memory (such as a One Time Programmable Read. Only Memory (OTPROM), a Programmable ROM (PROM), an Erasable and Programmable ROM (EPROM), an Electrically Erasable and Programmable ROM (EEPROM), a mask ROM, a flash ROM, a NAND flash memory, a NOR flash memory, or the like)

According to an embodiment, the internal memory 1132 is a Solid State Drive (SSD). The external memory 1134 further includes a flash drive, for example, a Compact Flash (CE), a Secure Digital (SD), a Micro Secure Digital (Micro-SD), a Mini Secure Digital (Mini-SD), an extreme Digital (xD), a memory stick, or the like. The external memory 1134 is functionally connected to the electronic device 1100 through various interfaces. According to an embodiment, the electronic device 1100 further includes a storage device (or storage medium) such as a hard disc drive.

The sensor module 1140 measures a physical quantity or sense an operating state of the electronic device 1100 and convert the measured or sensed information into an electric signal. The sensor module 1140 includes at least one of for example, a gesture sensor 1140A, a gyro sensor 1140B, an atmospheric pressure sensor 1140C, a magnetic sensor 1140D, an acceleration sensor 1140E, a grip sensor 1140F, a proximity sensor 1140G, a color sensor 1140H (such as Red, Green, and Blue (ROB) sensor), a biometric sensor 11401, a temperature/humidity sensor 1140J, an illumination sensor 1140K, and an Ultra Violet (UV) sensor 1140M, Additionally or alternatively, the sensor module 1140 includes, for example, an E-nose sensor, an electromyography (EMG) sensor, an electroencephalogram (EEG) sensor, an electrocardiogram (ECG) sensor, an Infrared (IR) sensor, an iris sensor, a fingerprint sensor, or the like. The sensor module 1140 further includes a control circuit for controlling one or more sensors included therein.

The input device 1150 includes a touch panel 1152, a (digital) pen sensor 1154, a key 1156, or an ultrasonic input device 1158. The touch panel 1152 recognizes a touch input based on at least one of for example, a capacitive type, a resistive type, an infrared type, and an acoustic wave type. In addition, the touch panel 1152 further includes a control circuit. The capacitive type touch panel recognizes physical contact or proximity. The touch panel 1152 further includes a tactile layer. In this case, the touch panel 1152 provides a user with a tactile reaction.

The (digital) pen sensor 1154 is implemented, for example, in the same or a similar method to receiving a user's touch input or using a separate sheet for recognition. The key 1156 includes, for example, a physical button, an optical key, or a keypad. The ultrasonic input unit 1158 identifies data by detecting an acoustic wave with a microphone of the electronic device 1100 through an input unit for generating an ultrasonic signal, and wireless recognition is possible. According to an embodiment, the electronic device 1100 receives a user input from an external device (such as a computer or server) connected thereto using the communication module 1120.

The display 1160 includes a panel 1162, a hologram device 1164, or a projector 1166. The panel 1162 is, for example, a Liquid Crystal Display (LCD), an Active Matrix Organic Light Emitting Diode (AM-OLED), or the like. The panel 1162 is implemented to be, for example, flexible, transparent, or wearable. The panel 1162 is formed as a single module together with the touch panel 1152. The hologram device 1164 shows a stereoscopic image in the air using interference of light. The projector 1166 displays an image by projecting light onto a screen. The screen is disposed in the interior of or on the exterior of the electronic device 1100. According to an embodiment, the display 1160 further includes a control circuit for controlling the panel 1162, the hologram device 1164, or the projector 1166.

The interface 1170 includes, for example, a High-Definition Multimedia interface (HDMI) 1172, a Universal Serial Bus (USB) 1174, an optical interface 1176, or a D-subminiature (D-sub) 1178. Additionally or alternatively, the interface 1170 includes, for example, a Mobile High-definition Link (MHL) interface, a Secure Digital (SD) card/Multi-Media Card (MMC) interface, or an Infrared Data Association (IrDA) standard interface,

The audio module 1180 bilaterally converts a sound and an electrical signal. The audio module 1180 processes sound information input or output through, for example, a speaker 1182, a receiver 1184, earphones 1186, the microphone 1188, or the like.

The camera module 1191 is a device for capturing a still image or a video, and according to an embodiment, includes one or more image sensors (such as a front sensor or a rear sensor), a lens, an Image Signal Processor (ISP), or a flash (such as an LED or xenon lamp).

The power management module 1195 manages the power of the electronic device 1100. The power management module 1195 includes, for example, a Power Management Integrated Circuit (PMIC), a charger Integrated Circuit (IC), or a battery or fuel gauge.

The PMIC is mounted, for example, in an integrated circuit or an SoC semiconductor. Charging methods is classified into a wired charging method and a wireless charging method. The charger IC charges a battery and prevents the introduction of over-voltage or over-current from a charger. According to an embodiment, the charger IC includes a charger IC for at least one of the wired charging method and the wireless charging method. Examples of the wireless charging method includes, for example, a magnetic resonance method, a magnetic induction method, and an electromagnetic wave method, and an additional circuit for wireless charging, such as a coil loop circuit, a resonance circuit, or a rectifier circuit, is added.

The battery gauge measures, for example, a residual quantity of the battery 1196, and a voltage, a current, or a temperature while charging. The battery 1196 stores or generates electricity and supplies power to the electronic device 1100 using the stored or generated electricity. The battery 1196 includes, for example, a rechargeable battery or a solar battery.

The indicator 1197 indicates a particular state of the electronic device 1100 or a part thereof (such as the AP 1110), such as a boot-up state, a message state, a charging state, or the like. The motor 1199 converts an electric signal into mechanical vibration. The electronic device 1100 includes a processing unit (such as a CPU) for supporting mobile TV. The processing device for supporting mobile TV processes, for example, media data associated with the standard of Digital Multimedia Broadcasting (DMB), Digital Video Broadcasting (DVB), a media flow, or the like. A thermal interface material (such as the sheet 1 of FIG. 1), according to an embodiment of the present disclosure, is applied to at least one element of the electronic device 1100.

The above described components of the electronic device according to various embodiments of the present disclosure is formed of one or more components, and a name of a corresponding component element is changed based on the type of electronic device. The electronic device according to the present disclosure includes one or more of the aforementioned components or further includes other additional components, or some of the aforementioned. components can be omitted. Further, some of the components of the electronic device according to the various embodiments of the present disclosure is combined to form a single entity, and thus, equivalently executes functions of the corresponding elements prior to the combination.

According to an embodiment of the present disclosure, a heat transfer apparatus includes a first thermal conductor (such as the heating element 14), a second thermal conductor (such as the heat dissipation plate 15), and an interface member (such as the sheet 1) for transferring heat between the first and second thermal conductors 14 and 15. A portion (such as the second layer 12) of the interface member 1 contains a thermoplastic material reacting with the heat. According to an embodiment of the present disclosure, the thermoplastic material (such as the second layer 12.) includes a Phase Change Material (PCM) that is to be transformed from the solid phase into the liquid phase by the heat. According to an embodiment of the present disclosure, the interface member (such as the sheet 1) includes a first layer (such as the second layer 12) containing the thermoplastic material, and at least one second layer (such as the third layer 13) disposed on the first layer (such as the second layer 12).

According to an embodiment of the present disclosure, the second layer (such as the third layer 13) contains a resilient material. According to an embodiment of the present disclosure, the second layer (such as the third layer 13) contains silicon. According to an embodiment of the present disclosure, the second layer (such as the third layer 13) has a different thermal conductivity from the first layer (such as the second layer 12). According to an embodiment of the present disclosure, the second layer (such as the third layer 13) has a different thickness from the first layer (such as the second layer 12). According to an embodiment of the present disclosure, the second layer (such as the third layer 13) has a different color from the first layer (such as the second layer 12). According to an embodiment of the present disclosure, the second layer (such as the third layer 13) is molded in such a manner that a surface of the first layer (such as the second layer 12) is subjected to surface treatment using a particular material (see FIG. 2).

According to an embodiment of the present disclosure, the interface member (such as the sheet 1-1) further includes at least one third layer (such as the third layer 13-2) disposed below the first layer (such as the second layer 12-1). According to another embodiment of the present disclosure, an electronic device 100 includes a display 22, a bracket 23 disposed below the display 22, a circuit board 3 disposed below the bracket 23, and an interface member (such as the sheet 1) for transferring heat between the circuit board 3 and the bracket 23. Here, a portion (such as the second layer 12) of the interface member 1 contains a Phase Change Material (PCM) that is changed from the solid phase into the liquid phase by the heat. According to another embodiment of the present disclosure, the interface member (such as the sheet 1) includes a first layer (such as the second layer 12) containing the PCM, and a second layer (such as the third layer 13) disposed below the first layer.

According to another embodiment of the present disclosure, the second layer (such as the third layer 13) contains a resilient material. According to another embodiment of the present disclosure, the second layer (such as the third layer 13) contains silicon. According to another embodiment of the present disclosure, the second layer (such as the third layer 13) has a different thermal conductivity from the first layer (such as the second layer 12), According to another embodiment of the present disclosure, the second layer (such as the third layer 13) is molded in such a manner that a surface of the first layer (such as the second layer 12) is subjected to surface treatment using a particular material (see FIG. 2). According to another embodiment of the present disclosure, the bracket 23 contains magnesium (Mg). According to another embodiment of the present disclosure, the circuit board 3 includes at least one electronic component mounted on a surface thereof (such as the substrate-upper-side mounted component 31), and the interface member (such as the sheet 1) is disposed between the at least one electronic component 31 and the bracket 23.

According to another embodiment of the present disclosure, the circuit board 3 and the bracket 23 is fastened to each other with a bolt, and the gap between the at least one electronic component (such as the substrate-upper-side mounted component 31) and the bracket 23 is maintained. According to another embodiment of the present disclosure, the at least one electronic component (such as the substrate-upper-side mounted component 31) includes an integrated circuit chip (such as the AP 31-1).

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A heat transfer apparatus comprising:
a first thermal conductor;
a second thermal conductor; and
an interface member configured to transfer heat between the first thermal conductor and second thermal conductor, wherein a portion of the interface member includes a thermoplastic material that reacts with the heat.

2. The heat transfer apparatus of claim I, wherein the thermoplastic material comprises a Phase Change Material (PCM) that transforms from a solid phase to a liquid phase via an application of the heat.

3. The heat transfer apparatus of claim 1, wherein the interface member comprises:
a first layer comprising the thermoplastic material; and
at least one second layer disposed on the first layer.

4. The heat transfer apparatus of claim 2, wherein the second layer includes a resilient material.

5. The heat transfer apparatus of claim wherein the second layer includes silicon.

6. The heat transfer apparatus of claim 2, wherein the second layer comprises a different conductivity value than a thermal conductivity value of the first layer.

7. The heat transfer apparatus of claim 2, wherein the second layer comprises a different thickness than a thickness of the first layer.

8. The heat transfer apparatus of claim 2, wherein the second layer comprises a different color than a color of the first layer.

9. The heat transfer apparatus of claim 2, wherein the second layer is molded in such a manner that a surface of the first layer is subjected to surface treatment using a particular material.

10. The heat transfer apparatus of claim 3, wherein the interface member comprises at least one third layer disposed below the first layer.

11. An electronic device comprising:
a display;
a bracket disposed below the display;
a circuit board disposed below the bracket; and
an interface member configured to transfer heat between the circuit board and the bracket, wherein a portion of the interface member includes a Phase Change Material (PCM) that is changed from a solid phase into a liquid phase via an application of heat.

12. The electronic device of claim 11, wherein the interface member comprises:
a first layer comprising the PCM; and
a second layer disposed below the first layer.

13. The electronic device of claim 12, wherein the second layer comprises a resilient material.

14. The electronic device of claim 12, wherein the second layer comprises silicon.

15. The electronic device of claim 12, wherein the second layer comprises a different thermal conductivity value than a thermal conductivity value of the first layer.

16. The electronic device of claim 12, wherein the second layer is molded in such a manner that a surface of the first layer is subjected to surface treatment using a particular material. The electronic device of claim 11, wherein the bracket comprises magnesium (Mg).

18. The electronic device of claim 11, wherein the circuit board comprises at least one electronic component mounted on a surface thereof, and the interface member is disposed between the at least one electronic component and the bracket.

19. The electronic device of claim 18, wherein the circuit board and the bracket are fastened to each other via a bolt, and a gap between the at least one electronic component and the bracket is maintained.

20. The electronic device of claim 18, wherein the electronic component comprises an integrated circuit chip.
